(19) United States
(12) Patent Application Publication
(10) Pub. No.: US 2026/0162924 A1
(43) Pub. Date: Jun. 11, 2026

(54) CHARGED PARTICLE BEAM ENERGY WIDTH REDUCTION APPARATUS, METHOD OF OPERATING THEREOF, AND CHARGED PARTICLE BEAM DEVICE

(71) Applicant: ICT Integrated Circuit Testing Gesellschaft für Halbleiterprüftechnik mbH, Heimstetten (DE)

(72) Inventor: Pieter Kruit, Delft (NL)

(73) Assignee: ICT Integrated Circuit Testing Gesellschaft für Halbleiterprüftechnik mbH, Heimstetten (DE)

(21) Appl. No.: 18/976,224

(22) Filed: Dec. 10, 2024

(51) Int. Cl. H01J 37/147; H01J 37/145; H01J 37/28

(52) U.S. Cl. CPC H01J 37/1477; H01J 37/145; H01J 37/28; H01J 2237/0451; H01J 2237/0475; H01J 2237/04926

(57) ABSTRACT

A charged particle beam energy width reduction apparatus for a charged particle beam device having an optical axis is described. The charged particle beam energy width reduction apparatus includes a first round lens configured to decelerate a primary charged particle beam and to focus the primary charged particle beam in a focusing plane; a charged particle deflector assembly configured to generate dispersion in the focusing plane, the charged particle deflector assembly comprising: a first electrostatic charged particle deflector arranged on the optical axis and comprising two flat conducting surfaces; and a second electrostatic charged particle deflector comprising two flat conducting surfaces; the charged particle beam energy width reduction apparatus further comprising: a beam limiting opening in an aperture body positioned in the focusing plane and off-axis with respect to the optical axis.

### TECHNICAL FIELD

Embodiments described herein relate to charged particle beam devices, and particularly to scanning electron microscopes (SEM). Embodiments relate to monochromators, i.e. energy width reduction apparatuses. Specifically, embodiments relate to charged particle beam energy width reduction apparatuses, charged particle beam devices, and methods of operating a charged particle beam device.

### BACKGROUND

Modern semiconductor technology has created a high demand for structuring and probing specimens in the nanometer or even in the sub-nanometer scale. Micrometer and nanometer-scale process control, inspection or structuring, is often done with charged particle beams, e.g. electron beams, which are generated, shaped, deflected and focused in charged particle beam devices, such as electron microscopes. For inspection purposes, charged particle beams offer a superior spatial resolution compared to, e.g., photon beams.

Reliably inspecting, imaging samples, and/or critical dimensioning (CD) measurements with a charged particle beam device at a good resolution is, however, challenging because the charged particle beam typically suffers from beam aberrations that limit the obtainable resolution.

Particularly for low voltage electron microscopes, achievable resolution is strongly influenced by the chromatic aberration. Particularly for low energy application, it is beneficial to reduce chromatic aberrations. The diameter of the aberration disc of the chromatic aberration in the Gaussian image plane of an objective is proportional to the relative energy width ΔE/E of the charged particle beam.

The electrons in an electron beam column are not monochromatic because of the emission process and the Boersch effect, that is, the broadening of the energy distribution because of stochastic Coulomb interaction so that the relative energy width is increased. In view of the above, the energy width ΔE amounts to approximately 0.5 eV to 1 eV in dependence upon the beam current.

The energy width ΔE of the electron beam, which is processed subsequently by the downstream electron-optical imaging system, can be reduced. For example, Wien filter arrangements or Omega filter arrangements can be provided as monochromators for charged particle beams. For example, in a Wien filter an electrostatic dipole field and a magnetic dipole field are superposed perpendicularly to each other. Existing monochromators can be complex and/or can be inflexible for operation.

In view of the above, it would be beneficial to provide charged particle beam devices with reduced chromatic aberrations, monochromators, i.e. energy width reduction systems, and methods of operating thereof.

### SUMMARY

In light of the above, a charged particle beam energy width reduction apparatus, a charged particle beam device, and a method of operating a charged particle beam according to the independent claims are provided. Further advantages, features, aspects and details that can be combined with embodiments described herein are evident from the dependent claims, the description and the drawings.

According to an embodiment, a charged particle beam energy width reduction apparatus for a charged particle beam device having an optical axis is provided. The charged particle beam energy width reduction apparatus includes a first round lens configured to decelerate a primary charged particle beam and to focus the primary charged particle beam in a focusing plane; a charged particle deflector assembly configured to generate dispersion in the focusing plane, the charged particle deflector assembly comprising: a first electrostatic charged particle deflector arranged on the optical axis and comprising two flat conducting surfaces; and a second electrostatic charged particle deflector comprising two flat conducting surfaces; the charged particle beam energy width reduction apparatus further comprising: a beam limiting opening in an aperture body positioned in the focusing plane and off-axis with respect to the optical axis.

According to an embodiment, a charged particle beam device is provided. The charged particle beam device includes a charged particle beam source configured to generated a primary charged particle beam; a charged particle beam energy width reduction apparatus according to any of embodiments of the present disclosure; and an objective lens configured to focus the primary charged particle beam.

According to an embodiment, a method of operating a charged particle beam device having a charged particle beam energy width reduction apparatus is provided. The method includes generating a primary charged particle beam; focusing the primary charged particle beam in a focusing plane with a first round lens and decelerating the primary charged particle beam with the first round lens; generating dispersion in the focusing plane with a charged particle deflector assembly comprising: a first electrostatic charged particle deflector arranged on an optical axis and comprising two flat conducting surfaces; and a second electrostatic charged particle deflector comprising two flat conducting surfaces; the method further comprising: reducing an energy width of the primary charged particle beam with a beam limiting opening in an aperture body positioned in the focusing plane and off-axis with respect to an optical axis.

### BRIEF DESCRIPTION OF THE DRAWINGS

So that the manner in which the above recited features of the present disclosure can be understood in detail, a more particular description, briefly summarized above, can be had by reference to embodiments. The accompanying drawings relate to one or more embodiments and are described in the following.

FIG. 1 shows a schematic view of a charged particle beam device having a charged particle beam energy width reduction apparatus according to embodiments described herein;

FIG. 2 shows a schematic view of a charged particle beam energy width reduction apparatus according to embodiments of the present disclosure;

FIG. 3 shows a schematic view of another charged particle beam energy width reduction apparatus according to embodiments of the present disclosure;

FIG. 4 shows an example of aperture opening to illustrate a beam limiting opening or a beam limiting slit utilized in embodiments of the present disclosure;

FIG. 5 shows a flow chart to illustrate methods of operating a charged particle beam energy width reduction apparatus or methods of operating a charged particle beam device according to embodiments of the present disclosure;

FIG. 6A shows schematically a simulation of a charged particle beam energy width reduction apparatus, and

FIG. 6B shows an enlarged view of the dashed area in FIG. 6A.

### DETAILED DESCRIPTION

Reference will now be made in detail to the various embodiments, one or more examples of which are illustrated in the figures. Within the following description of the drawings, same reference numbers refer to same components. Generally, only the differences with respect to individual embodiments are described. Each example is provided by way of explanation and is not meant as a limitation. Further, features illustrated or described as part of one embodiment can be used on or in conjunction with other embodiments to yield yet a further embodiment. It is intended that the description includes such modifications and variations.

Embodiments of the present disclosure relate to charged particle beam energy width reduction apparatuses, for example, electron beam monochromators. The energy width or energy spread in charged particle beams, such as electron beams, can be reduced resulting in a higher resolution, for example, higher resolution of an SEM image. Particularly for low landing energies, the resolution can be improved by reducing chromatic aberrations. Chromatic aberrations can be reduced by reducing the energy width (or the energy spread) of the charged particle beam.

According to an embodiment, a charged particle beam energy width reduction apparatus for a charged particle beam device having an optical axis is provided. The charged particle beam energy width reduction apparatus includes a first round lens configured to decelerate a primary charged particle beam and to focus the primary charged particle beam in a focusing plane and a charged particle deflector assembly configured to generate dispersion. The charged particle deflector assembly includes at least a first electrostatic charged particle deflector arranged on the optical axis and comprising two flat conducting surfaces and a second electrostatic charged particle deflector comprising two flat conducting surfaces. The charged particle beam energy width reduction apparatus further includes a beam limiting opening in an aperture body positioned in the focusing plane and off-axis with respect to the optical axis.

Embodiments of the present disclosure can provide monochromators, i.e. charged particle beam energy width reduction apparatuses, which are less complex. For example, only (“standard”) round electrostatic lenses and (“standard”) electrostatic deflectors can be used.

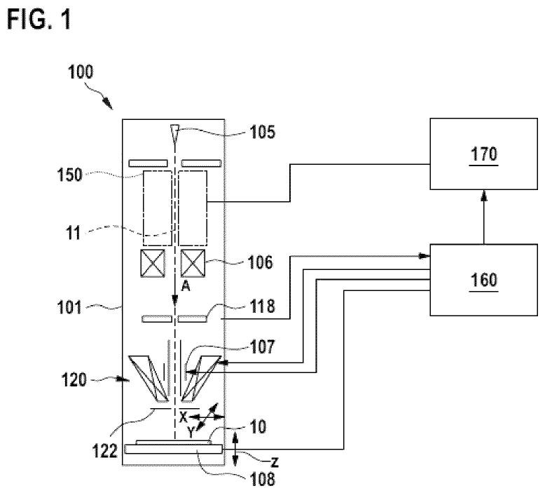

FIG. 1 is a schematic view of a charged particle beam device 100 for inspecting and/or imaging a sample 10 according to embodiments described herein. The charged particle beam device 100 includes a charged particle source 105, particularly an electron source, for emitting a charged particle beam, particularly an electron beam, propagating along an optical axis 11. The charged particle beam device 100 further includes a sample stage 108, and a focusing lens 120, particularly an objective lens, for focusing the charged particle beam on the sample 10 that is placed on the sample stage 108. The charged particle beam device 100 further includes a charged particle detector 118, particularly an electron detector, for detecting signal particles (secondary electrons and/or backscattered electrons) emitted from the sample 10.

An image generation unit 160 can be provided that is configured to generate one or more images of the sample 10 based on the charged particle signal received from the charged particle detector 118. The image generation unit 160 can forward the one or more images of the sample to a controller 170.

The sample stage 108 can be a movable stage. In particular, the sample stage 108 can be movable in the Z-direction, i.e., in the direction of the optical axis 11. In some embodiments, the sample stage 108 can also be movable in a plane perpendicular to the optical axis 11 (also referred to herein as the X-Y-plane). By moving the sample stage 108 in the X-Y-plane, a specified surface region of the sample 10 can be moved into an area below the focusing lens 120, such that the specified surface region can be imaged by focusing the charged particle beam thereon.

The beam-optical components of the charged particle beam device 100 are typically placed in a vacuum chamber 101 that can be evacuated, such that the charged particle beam can propagate along the optical axis 11 from the charged particle source 105 toward the sample stage 108 and hit the sample 10 under a sub-atmospheric pressure, e.g. a pressure below 10⁻³mbar or a pressure below 10⁻⁵mbar.

In some embodiments, the charged particle beam device 100 can be an electron microscope, particularly a scanning electron microscope. A scan deflector 107 can be provided for scanning the charged particle beam over a surface of the sample 10 along a predetermined scanning pattern, e.g., in the X-direction and/or in the Y-direction.

In some embodiments, a condenser lens system, including e.g. a condenser lens 106, can be arranged downstream of the charged particle source 105, particularly for collimating the charged particle beam propagating toward the focusing lens 120.

Further, as shown in FIG. 1, a charged particle beam energy width reduction apparatus 150 is provided. The charged particle beam device 100 can include a charged particle beam energy width reduction apparatus according to any of the embodiments of the present disclosure.

In some embodiments, the focusing lens 120 is an objective lens configured to focus the charged particle beam on the sample 10, particularly a magnetic objective lens, an electrostatic magnetic lens, or more particularly a combined magnetic-electrostatic lens. For example, FIG. 1 shows an electrode 122 included in the objective lens for focusing and decelerating the primary charged particle beam. The primary charged particle beam or primary electron beam can be focused on the sample 10 with a low landing energy. For example, the landing energy can be 500 eV or below, such as 200 eV or below.

One or more surface regions of the sample 10 can be inspected and/or imaged with the charged particle beam device 100. The term “sample” as used herein may relate to a specimen or a substrate, e.g., with one or more layers or features formed thereon. For example, the specimen or substrate can be a semiconductor wafer, a glass substrate, a flexible substrate, such as a web substrate, or another sample that is to be inspected.

For inspecting the sample 10 with the charged particle beam, the charged particle beam can be focused on a sample surface with the focusing lens 120. Secondary electrons and/or backscattered electrons (referred to as “signal electrons”) are emitted from the sample when the charged particle beam impinges on the sample surface. The signal electrons provide information about spatial characteristics and dimensions of features of the sample, and can be detected with the charged particle detector 118. By scanning the charged particle beam over the sample surface, e.g. with the scan deflectors 107, and detecting the signal electrons as a function of the generation position of the signal electrons, the sample surface or a portion thereof can be imaged, e.g., with the image generation unit 160 that can be configured to provide an image of the sample 10 based on the received signal electrons.

According to an embodiment, a charged particle beam device is provided. The charged particle beam device includes a charged particle beam source configured to generated a primary charged particle beam, a charged particle beam energy width reduction apparatus according to any of the embodiments of the present disclosure, and an objective lens configured to focus the primary charged particle beam. According to some embodiments, which can be combined with other embodiments described herein, the objective lens can be a combined magnetic electrostatic lens configured to decelerate the primary charged particle beam to a landing energy of 500 eV or below.

As shown in FIG. 1, the charged particle beam energy width reduction apparatus 150 can be upstream of the condenser lens 106. As described in more detail below, the charged particle beam energy width reduction apparatus 150 includes a lens. According to some embodiments, the lens of the charged particle beam energy width reduction system can optionally be used as a condenser lens, for example, instead of the condenser lens 106 shown in FIG. 1. For example, the lens of the charged particle beam energy width reduction apparatus can be an electrostatic lens or can include an electrostatic lens, particularly for decelerating of the primary charged particle beam, e.g. when the monochromator is an operating mode. According to some embodiments, which can be combined with other embodiments described herein, a first round lens of a charged particle beam energy width reduction apparatus can provide a condenser lens for the charged particle beam device.

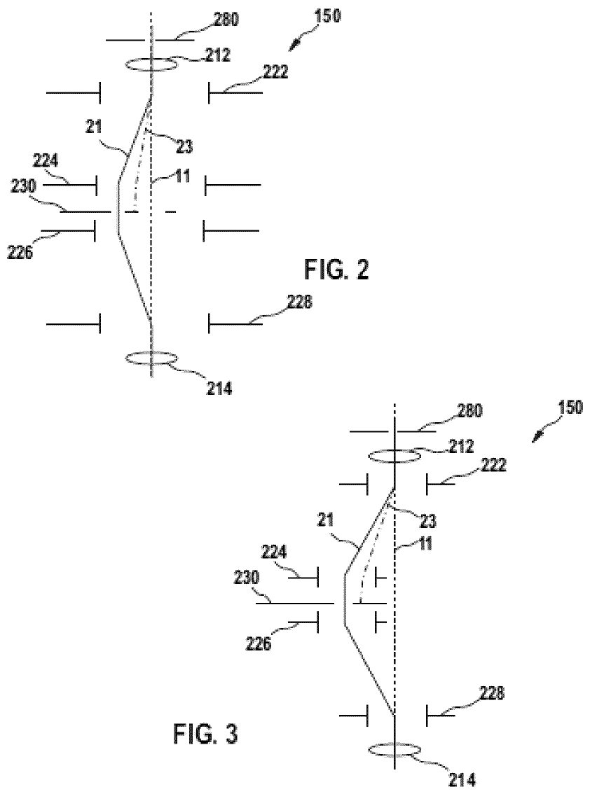

FIG. 2 shows a charged particle beam energy width reduction apparatus 150. The charged particle beam energy width reduction apparatus can also be referred to as the monochromator. The monochromator includes a first round lens 212. According to some embodiments, the first round lens 212 can be arranged on the optical axis 11. The first round lens is a round lens and particularly an electrostatic lens configured to decelerate the primary charged particle beam. The primary charged particle beam is focused in a focusing plane.

A first electrostatic charged particle deflector 222 deflects the charged particle beam away from the optical axis 11. The first electrostatic charged particle deflector 222 includes two flat conducting surfaces to generate an electrostatic dipole field. In addition to the deflection, the dispersion is generated by the first electrostatic charged particle deflector 222. A second electrostatic charged particle deflector 224 including two flat conducting surfaces is provided downstream of the first electrostatic charged particle deflector. The second electrostatic charged particle deflector 224 deflects the charged particle beam with a deflection direction opposite to the deflection direction of the first electrostatic charged particle deflector 222. For example, the charged particle beam can be parallel to the optical axis 11 after the second electrostatic charged particle deflector 224.

A beam limiting aperture 230 is provided in the focusing plane of the first round lens 212. The beam limiting aperture includes an aperture body and has a beam limiting opening, which is off-axis with respect to the optical axis 11. According to some embodiments, which can be combined with other embodiments described herein, the beam limiting opening can be a beam limiting slit. The beam limiting opening or beam limiting slit allows charged particles, such as electrons, with a predetermined energy (or nominal energy) to pass. Charged particles, such as electrons, deviating too much from the predetermined energy are blocked by the beam limiting aperture 230.

As schematically shown in FIG. 2, a charged particle beam 21 with a predetermined energy can path through the beam limiting opening of the beam limiting aperture 230. The dispersion introduced by the first electrostatic charged particle deflector generates a different beam path 23 for a different beam energy. Accordingly, electrons having an energy different than the predetermined energy can be blocked by the aperture body of the beam limiting aperture to reduce the energy width (or the energy spread) of the primary charged particle beam.

According to an embodiment, a charged particle beam energy width reduction apparatus for a charged particle beam device having an optical axis is provided. The charged particle beam energy width reduction apparatus includes a first round lens configured to decelerate a primary charged particle beam and to focus the primary charged particle beam in a focusing plane and a charged particle deflector assembly configured to generate dispersion. The charged particle deflector assembly includes at least a first electrostatic charged particle deflector arranged on the optical axis and comprising two flat conducting surfaces and a second electrostatic charged particle deflector comprising two flat conducting surfaces. The charged particle beam energy width reduction apparatus further includes a beam limiting opening in an aperture body positioned in the focusing plane and off-axis with respect to the optical axis.

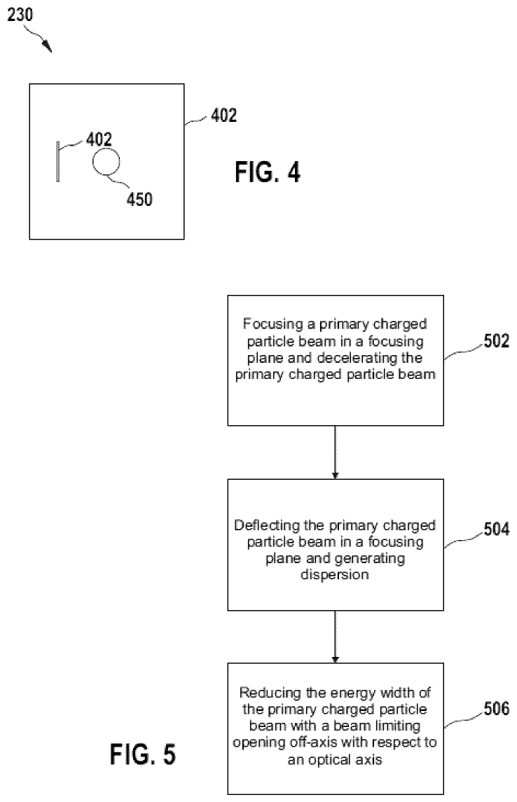

According to some embodiments, which can be combined with other embodiments described herein, the displacement of the charged particle beam from the optical axis 11 can be, for example, 0.5 mm or above, such as 1 mm or above. Accordingly, for a deceleration of 1000 EV or below, such as 500 eV or below, an opening size or a slit size for delimiting the primary charged particle beam, and particularly delimiting the energy width of the primary charged particle beam can be in a range of 50 nm or above. For example, additionally or alternatively, the opening size or slit size can be to 2 μm or below. For example, the opening size or slit size can be 100 nm to 1500 nm, such as 200 nm to 1000 nm. FIG. 4 shows a beam limiting aperture 230. The beam limiting aperture includes an aperture body. A beam limiting opening 402 is provided to block a portion of a charged particle beam or an electron beam and particularly a portion with an energy deviating from a predetermined energy. Further, an on-axis opening 450 can be provided as described in more detail below.

According to some embodiments, which can be combined with other embodiments described herein, the first round lens can be configured to decelerate the primary charged particle beam to an energy of 500 eV or less. Further, the dispersion can be generated in the plane of the beam limiting opening. According to embodiments of the present, the charged particle deflector assembly is purely electrostatic, particularly wherein the charged particle deflector assembly does not include one or more magnetic deflectors. In light of the above, magnetic elements in a monochromator or charged particle beam energy width reduction apparatus can be avoided. Hysteresis effects or drifts can be reduced or avoided.

A beam limiting opening according to embodiments of the present disclosure can be provided in an aperture body and is configured to block a portion of a charged particle beam or an electron beam and particularly a portion with an energy deviating from a predetermined energy. It is also possible to provide an electron selection means as a beam limiting opening, e.g. a knife edge, that blocks electrons deviating from the predetermined energy in only one of either positive or negative deviation.

According to some embodiments, which can be combined with other embodiments described herein, the beam limiting opening can be a beam limiting slit. For example, the opening or the slit can have a width of 2 μm or below, particularly 500 nm or below.

In light of the dimensions of the opening or the slit, it is beneficial to provide a further deflector to be capable to deflect the charged particle beam in a second direction perpendicular or essentially perpendicular to the direction of dispersion. Accordingly, the charged particle beam can be deflected in the second direction to pass through the beam limiting opening or the beam limiting slit. According to some embodiments, which can be combined with other embodiments described herein, the charged particle beam energy width reduction apparatus (or monochromator) can further include a fifth deflector configured to deflect the primary charged particle beam in a direction orthogonal to the deflection direction of the first electrostatic charged particle deflector and the second electrostatic charged particle deflector.

The charged particle beam energy width reduction apparatus 150, as exemplarily shown in FIG. 2, can further include the third electrostatic charged particle deflector 226 and a fourth electrostatic charged particle deflector 228. Each of the third electrostatic charged particle deflector and the fourth electrostatic charged particle deflector include two flat conducting surfaces. For example, the first to fourth electrostatic charged particle deflector deflect the beam in one direction. The deflection direction is illustrated by the paper plane in FIG. 2, which can correspond e.g. to the x-direction indicated in FIG. 1. According to some embodiments, which can be combined with other embodiments described herein, the flat conducting surfaces of the electrostatic charged particle deflectors can have an orientation with a surface normal perpendicular to the optical axis.

According to some embodiments, which can be combined with other embodiments described herein, the charged particle deflector assembly having the four electrostatic charged particle deflectors can have a symmetric arrangement. Thus, the overall dispersion after the charged particle beam energy width reduction apparatus 150 is essentially zero or zero. Yet further, as exemplarily shown in FIG. 2, a second round lens 214 configured to accelerate the primary charged particle beam can be provided.

The electrostatic charged particle deflectors shown in the figures and described herein, are configured for a deflection in one direction, i.e. the deflectors include two flat conducting surfaces to provide a dipole. According to additional modification the electrostatic charged particle deflectors can include two or more flat conducting surfaces, for example, 2, 4, 6 or 8 conducting surfaces. Accordingly, the direction of deflection can be controlled. Further, in addition to a deflection field a higher order field, such as a quadrupole field, can be generated. For example, astigmatism can additionally be corrected.

According to some embodiments, which can be combined with other embodiments described herein, the first round lens, the first to fourth electrostatic charged particle deflector, and the second round lens can be arranged on the optical axis 11.

The second electrostatic charged particle deflector 224 and the third electrostatic charged particle deflector 226 are illustrated in FIG. 2 to be on-axis. According to some embodiments, which can be combined with other embodiments described herein, the deflectors can have deflector plates, i.e. the flat conducting surfaces, arranged symmetrically around the optical axis 11. As shown in FIG. 3, the deflectors are displaced with respect to the optical axis, i.e. the deflectors or the deflector plates are not arranged symmetrical with respect to the optical axis.

According to some embodiments, which can be combined with other embodiments described herein, a charged particle beam can travel outside the center of a deflector or a center of deflector can be virtually shifted by not having anti-symmetric voltages on the flat conducting surfaces, but rather having voltages with asymmetric offset.

FIG. 3 shows another charged particle beam energy width reduction apparatus 150 according to some embodiments. As compared to FIG. 2, The second electrostatic charged particle deflector 224 and the third electrostatic charged particle deflector 226 are shifted to be position off-axis, i.e. a center or symmetry axis of the electrostatic charged particle deflector is disposed to be off the optical axis.

According to some embodiments, which can be combined with other embodiments described herein, a charged particle beam energy width reduction apparatus can further include a second round lens configured to accelerate the primary charged particle beam. The charged particle deflector assembly further can further include a third electrostatic charged particle deflector comprising two flat conducting surfaces and a fourth electrostatic charged particle deflector arranged on the optical axis and comprising two flat conducting surfaces. For example, the first electrostatic charged particle deflector and the second electrostatic charged particle deflector can be arranged between the first round lens and the beam limiting opening, and the third electrostatic charged particle deflector and the fourth electrostatic charged particle deflector can be arranged between the beam limiting opening and the second round lens.

According to some embodiments, which can be combined with other embodiments described herein, the monochromator or charged particle beam energy width reduction apparatus according to embodiments of the present disclosure can be used in a charged particle beam device configured for low landing energies and/or can be utilized in methods of operating a charged particle beam device accordingly. For example, a loss of resolution due to chromatic aberration in low landing energy SEM can be beneficial to overcome in a critical dimensioning-(CD)-SEM, particularly for EUV resists. A low landing energy can reduce or avoid damage to the sample to be measured or inspected. Accordingly, the beam current of the charged particle beam, particularly an electron beam, can be limited. FIG. 2 shows an entrance aperture 280 with an entrance aperture opening. According to some embodiments, which can be combined with other embodiments described herein, an entrance aperture opening of a charged particle beam energy width reduction apparatus or of a charged particle beam device, respectively, can be configured to limit the beam current to 10 nA or less.

FIG. 5 shows a flow chart to illustrate methods of operating a charged particle beam energy width reduction apparatus or methods of operating a charged particle beam device according to embodiments of the present disclosure. In a charged particle beam device, a primary charged particle beam is generated. The energy width or energy spread of primary charged particle beam device can be reduced by a monochromator or charged particle beam energy width reduction apparatus. As illustrated by operation 502, the primary charged particle beam is focused in a focusing plane with the first round lens and decelerated with the first round lens. A charged particle deflector assembly generates dispersion in the focusing plane of the first round lens (see operation 504). The charged particle deflector assembly includes a first electrostatic charged particle deflector arranged on the optical axis and comprising two flat conducting surfaces and a second electrostatic charged particle deflector comprising two flat conducting surfaces. At operation 506, the energy width of the primary charged particle beam is reduced in the focusing plane and off-axis with respect to the optical axis of the charged particle beam device.

Accordingly, dispersion is generated in a focusing plane of the first round lens, and particularly an electrostatic first round lens. The dispersion that has been introduced by the first electrostatic charged particle deflector and the second electrostatic charged particle deflector can be reduced (or compensated) with the third electrostatic charged particle deflector and a fourth electrostatic charged particle deflector. According to some embodiments, would can be combined with other embodiments described herein, the charged particle deflector assembly including the first deflector to the fourth deflector has a symmetric arrangement to avoid or minimize dispersion after the monochromator or charged particle beam energy width reduction apparatus. According to some embodiments, which can be combined with other embodiments described herein, the primary charged particle beam can be accelerated after passing through the beam limiting opening by a second round lens, particularly the second electrostatic round lens.

As described above, an entrance aperture opening can be provided to delimit the beam current of the charged particle beam device. According to some embodiments, which can be combined with other embodiments described herein, the method can further include limiting the beam current to 10 nA or less. Further, the first round lens can decelerate the primary charged particle beam to 500 eV or less, particularly in the plane of the beam limiting opening or the beam limiting slit.

Particularly for embodiments including a configuration as exemplarily shown in FIG. 2, wherein the first round lens 212 and the second round lens 214 are provided on axis, i.e. on the optical axis 11, the charged particle beam energy width reduction apparatus according to embodiments allows for different modes of operation. In a first mode of operation, the charged particle beam energy width reduction apparatus can be switched on and the primary charged particle beam is deflected by the deflector assembly through the beam limiting opening of the aperture body 232 reduce the energy width. Further, in a second mode of operation, the charged particle beam energy width reduction apparatus can be switched off. The first electrostatic charged particle deflector 222 can be switched off and the fourth electrostatic charged particle deflector 228 can be switched off. Additionally, the second electrostatic charged particle deflector 224 and the third electrostatic charged particle deflector 226 can also be switched off. Accordingly, the primary charged particle beam travels along the optical axis 11. For example, the primary charged particle beam can pass through the on-axis opening 450 shown in FIG. 4. Particularly, the on-axis opening 450 can be configured not to delimit the beam and/or influence the beam, No energy width reduction takes place. Thus, contrary to Omega-filters and to filters having a beam limiting opening on the optical axis, charged particle beam energy width reduction apparatus can be switched on or off without further influence on a charged particle beam device.

According to some embodiments, which can be combined with other embodiments described herein, the charged particle beam device can have a first mode of operation, in which the charged particle beam energy width reduction apparatus is switched on and can have a second mode of operation, in which the charged particle beam energy width reduction apparatus is switched off such that the primary charged particle beam travels along an optical axis of the charged particle beam device.

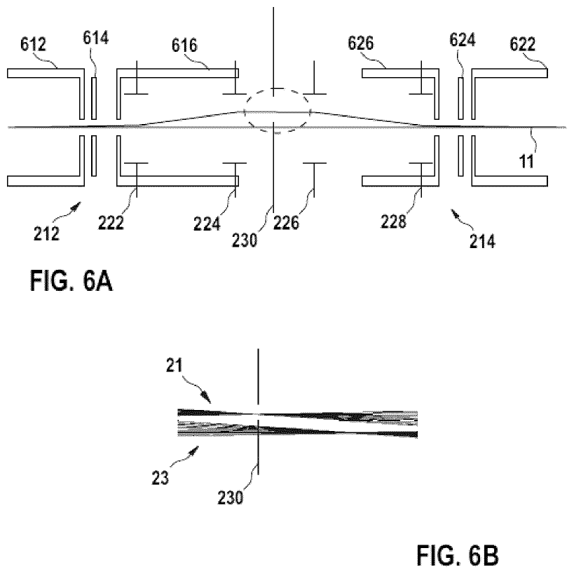

FIG. 6A schematically shows a simulation of a charged particle beam energy width reduction apparatus. The first round lens 212 is provided by three electrodes, i.e. a first electrode 612 and second electrode 614, and a third electrode 616 of the first round lens. The second round lens 214 is provided by three electrodes, i.e. a first electrode 626 and second electrode 624, and a third electrode 622 of the second first round lens 214.

A round lens implemented as or including an electrostatic lens with three electrodes allows to decelerate or accelerate the charged particle beam while one of the electrodes can be utilized to tune the focus position of the round lens.

The charged particle beam, for example, the electron beam is deflected by the charged particle deflector assembly having the first electrostatic charged particle deflector 222, the second electrostatic charged particle deflector 224, the third electrostatic charged particle deflector 226 and the fourth electrostatic charged particle deflector 228. The arrangement shown in FIG. 6A is similar to the exemplary arrangement shown in FIG. 2. FIG. 6B shows an enlarged view at the encircled area with the dashed lines in FIG. 6A. It is to be noted that the distances from the optical axis 11 of the elements, components, beams, and structures are not drawn to scale. Additionally, the slit width or opening width in FIGS. 6A and 6B is not drawn to scale.

According to some embodiments, which can be combined with other embodiments described herein, and as exemplarily shown in FIG. 6A, each of the first round lens and the second round lens can include three lens electrodes. Particularly, the lens electrodes can be connected to voltage supplies. The first round lens and the second round lens can be configured for decelerating and accelerating, respectively, of the primary charged particle beam. The beam energy at the beam limiting aperture 230 can be reduced by decelerating of the primary charged particle beam with the first round lens 212 and can be increased after the beam limiting aperture 230 with the second round lens 214.

The energy width reduction capability for reducing the energy width of the primary charged particle beam is exemplarily shown in FIG. 6B. The charged particle beam 21 passing through the beam limiting opening of the beam limiting aperture 230 and the charged particles on the different beam path 23 have a simulated energy difference of 1 eV. Accordingly, the simulation shows that the charged particles blocked by the beam limiting aperture 230 have an energy deviating by a few 0.1 eV, particularly considering that the beam limiting opening is not drawn to scale. Accordingly, an energy width of 0.2 eV or below 0.2 eV can be provided by the charged particle beam energy width reduction apparatus.

As described with respect to FIG. 1, according to any embodiment, a charged particle beam device is provided. The charged particle beam device includes a charged particle beam source configured to generated a primary charged particle beam, a charged particle beam energy width reduction apparatus according to any of the embodiments of the present disclosure, and an objective lens configured to focus the primary charged particle beam.

According to some embodiments, which can be combined with other embodiments described herein, a charged particle beam device can include an entrance aperture opening configured to limit the beam current to less than 10 nA. Embodiments of the present disclosure are particularly sensitive to electron-electron-interaction. Accordingly, a limitation of the beam current before the charged particle beam enters the monochromator is beneficial. Further, the charged particle beam system can include a condenser lens. The charged particle beam energy width reduction apparatus can be provided between the charged particle beam source and the condenser lens and the entrance aperture opening is provided between the charged particle beam source and the charged particle beam energy width reduction apparatus. For example, each element of the charged particle beam energy width reduction apparatus can be a few millimeters in height, e.g. 10 mm or below or even 4 mm or below. A distance between a first electrostatic charged particle deflector and a second beam electrostatic charged particle deflector or a beam limiting aperture can be a few centimeters, e.g. 1 cm to 4 cm, to allow for the dispersion to gain in space. Thus, a charged particle beam energy width reduction apparatus can be close to or partly located in a gun chamber and a beam current is reduced before the charged particle beam energy width reduction apparatus.

As described above, the monochromator or charged particle beam energy width reduction apparatus according to embodiments of the present disclosure can be provided, which is simpler as compared to omega filter arrangements or Wien filter arrangements. Only round electrostatic lenses and electrostatic deflectors are used. For example, if an energy width of Schottky emitter of 0.6 eV energy width or energy spread is reduce to about 0.15 eV with embodiments of the present disclosure, a beam current can be increased by a factor of 4 (at the same resolution), the spot size can be reduced by a factor of 2 (with reduced current) or the energy of the beam can be reduced by about a factor of 2.5 without loss of resolution. Particularly for low landing energies the resolution might be improved or the landing energy can be further reduced without loss of resolution.

In light of the above, a plurality of embodiments are provided in the present disclosure, some of which are outlined in the following embodiments.

Embodiment 1. A charged particle beam energy width reduction apparatus for a charged particle beam device having an optical axis, comprising: a first round lens configured to decelerate a primary charged particle beam and to focus the primary charged particle beam in a focusing plane; a charged particle deflector assembly configured to generate dispersion in the focusing plane, the charged particle deflector assembly comprising: a first electrostatic charged particle deflector arranged on the optical axis and comprising two flat conducting surfaces; and a second electrostatic charged particle deflector comprising two flat conducting surfaces; the charged particle beam energy width reduction apparatus further comprising: a beam limiting opening in an aperture body positioned in the focusing plane and off-axis with respect to the optical axis.

Embodiment 2. The charged particle beam energy width reduction apparatus according to embodiment 1, further comprising: a second round lens configured to accelerate the primary charged particle beam, and wherein the charged particle deflector assembly further comprises: a third electrostatic charged particle deflector comprising two flat conducting surfaces; and a fourth electrostatic charged particle deflector arranged on the optical axis and comprising two flat conducting surfaces.

Embodiment 3. The charged particle beam energy width reduction apparatus according to embodiment 2, wherein the first electrostatic charged particle deflector and the second electrostatic charged particle deflector are arranged between the first round lens and the beam limiting opening, and wherein the third electrostatic charged particle deflector and the fourth electrostatic charged particle deflector are arranged between the beam limiting opening and the second round lens.

Embodiment 4. The charged particle beam energy width reduction apparatus according to any of embodiments 2 to 3, wherein second electrostatic charged particle deflector and the third electrostatic charged particle deflector are arranged symmetric with respect to the optical axis.

Embodiment 5. The charged particle beam energy width reduction apparatus according to any of embodiments 1 to 4, wherein at least one of the first electrostatic charged particle deflector and the second electrostatic charged particle deflector comprises 4 or more flat conductive surfaces configured to generate an electrostatic field with an order higher than a dipole.

Embodiment 6. The charged particle beam energy width reduction apparatus according to any of embodiments 1 to 4, further comprising:
an entrance aperture opening configured to limit the beam current to less than 10 nA.

Embodiment 7. The charged particle beam energy width reduction apparatus according to any of embodiments 1 to 5, wherein the first round lens is configured to decelerate the primary charged particle beam to an energy of 500 eV or less.

Embodiment 8. The charged particle beam energy width reduction apparatus according to any of embodiments 1 to 6, wherein the dispersion is generated in a plane of the beam limiting opening and wherein the charged particle deflector assembly is purely electrostatic, particularly wherein the charged particle deflector assembly does not include one or more magnetic deflectors.

Embodiment 9 The charged particle beam energy width reduction apparatus according to any of embodiments 1 to 8, wherein the first electrostatic charged particle deflector generates at least 60% of the dispersion provided at the beam limiting opening, particularly at least 90% of the dispersion provided at the beam limiting opening.

Embodiment 10. The charged particle beam energy width reduction apparatus according to any of embodiments 1 to 9, wherein the beam limiting opening is a beam limiting slit.

Embodiment 11. The charged particle beam energy width reduction apparatus according to embodiment 10, wherein the beam limiting slit has a width of 2μm or below, particularly 500 nm or below.

Embodiment 12. The charged particle beam energy width reduction apparatus according to any of embodiments 1 to 11, further comprising: a fifth deflector configured to deflect the primary charged particle beam in a direction orthogonal to a deflection direction of the first electrostatic charged particle deflector and the second electrostatic charged particle deflector.

Embodiment 13. The charged particle beam energy width reduction apparatus according to any of embodiments 1 to 10, wherein each of the first round lens and the second round lens comprises three lens electrodes.

Embodiment 14. A charged particle beam device, comprising: a charged particle beam source configured to generated a primary charged particle beam; a charged particle beam energy width reduction apparatus according to any of embodiments 1 to 5 or 7 to 13; and an objective lens configured to focus the primary charged particle beam.

Embodiment 15. The charged particle beam system of embodiment 14,further comprising: an entrance aperture opening configured to limit the beam current to less than 10 nA.

Embodiment 16. The charged particle beam device of any of embodiments 14 to 15, further comprising a condenser lens, wherein the charged particle beam energy width reduction apparatus is provided between the charged particle beam source and the condenser lens and wherein the entrance aperture opening is provided between the charged particle beam source and the charged particle beam energy width reduction apparatus.

Embodiment 17. The charged particle beam device according to any of embodiments 14 to 16, wherein the objective lens is a combined magnetic electrostatic lens configured to decelerate the primary charged particle beam to a landing energy of 500 eV or below.

Embodiment 18. The charged particle beam device according to any of embodiments 14 to 17, wherein the first round lens of the charged particle beam energy width reduction apparatus provides a condenser lens for the charged particle beam device.

Embodiment 19. A method of operating a charged particle beam device having a charged particle beam energy width reduction apparatus, comprising: generating a primary charged particle beam; focusing the primary charged particle beam in a focusing plane with a first round lens and decelerating the primary charged particle beam with the first round lens; generating dispersion in the focusing plane with a charged particle deflector assembly comprising: a first electrostatic charged particle deflector arranged on an optical axis and comprising two flat conducting surfaces; and a second electrostatic charged particle deflector comprising two flat conducting surfaces; the method further comprising: reducing an energy width of the primary charged particle beam with a beam limiting opening in an aperture body positioned in the focusing plane and off-axis with respect to an optical axis.

Embodiment 20. The method of embodiment 19, further comprising: reducing the generated dispersion with the charged particle deflector assembly further comprising: a third electrostatic charged particle deflector comprising two flat conducting surfaces; and a fourth electrostatic charged particle deflector arranged on the optical axis and comprising two flat conducting surfaces.

Embodiment 21. The method of any of embodiments 19 to 20, further comprising: accelerating the primary charged particle beam with a second round lens.

Embodiment 22. The method of any of embodiments 19 to 21, further comprising: limiting the beam current to 10 nA or less.

Embodiment 23. The method of any of embodiments 19 to 22, wherein the first round lens reduces an energy of the primary charged particle beam to 500 eV or less.

Embodiment 24. The method of any of embodiments 19 to 23, wherein the charged particle beam device has a first mode of operation, in which the charged particle beam energy width reduction apparatus is switched on and has a second mode of operation, in which the charged particle beam energy width reduction apparatus is switched off such that the primary charged particle beam travels along an optical axis of the charged particle beam device.

While the foregoing is directed to embodiments, other and further embodiments can be devised without departing from the scope thereof, and the scope thereof is determined by the claims that follow.

What is claimed is:

1. A charged particle beam energy width reduction apparatus for a charged particle beam device having an optical axis, comprising:
a first round lens configured to decelerate a primary charged particle beam and to focus the primary charged particle beam in a focusing plane;
a charged particle deflector assembly configured to generate dispersion in the focusing plane, the charged particle deflector assembly comprising:
a first electrostatic charged particle deflector arranged on the optical axis and comprising two flat conducting surfaces; and
a second electrostatic charged particle deflector comprising two flat conducting surfaces;
the charged particle beam energy width reduction apparatus further comprising:
a beam limiting opening in an aperture body positioned in the focusing plane and off-axis with respect to the optical axis.

2. The charged particle beam energy width reduction apparatus according to claim 1, further comprising:
a second round lens configured to accelerate the primary charged particle beam, and wherein the charged particle deflector assembly further comprises: a third electrostatic charged particle deflector comprising two flat conducting surfaces, and a fourth electrostatic charged particle deflector arranged on the optical axis and comprising two flat conducting surfaces.

3. The charged particle beam energy width reduction apparatus according to claim 2, wherein the first electrostatic charged particle deflector and the second electrostatic charged particle deflector are arranged between the first round lens and the beam limiting opening, and wherein the third electrostatic charged particle deflector and the fourth electrostatic charged particle deflector are arranged between the beam limiting opening and the second round lens.

4. The charged particle beam energy width reduction apparatus according to claim 2, wherein second electrostatic charged particle deflector and the third electrostatic charged particle deflector are arranged symmetric with respect to the optical axis.

5. The charged particle beam energy width reduction apparatus according to claim 1, wherein at least one of the first electrostatic charged particle deflector and the second electrostatic charged particle deflector comprises 4 or more flat conductive surfaces configured to generate an electrostatic field with an order higher than a dipole.

6. The charged particle beam energy width reduction apparatus according to claim 1, further comprising an entrance aperture opening configured to limit the beam current to less than 10 nA.

7. The charged particle beam energy width reduction apparatus according to claim 1, wherein the first round lens is configured to decelerate the primary charged particle beam to an energy of 500 eV or less.

8. The charged particle beam energy width reduction apparatus according to claim 1, wherein the dispersion is generated in a plane of the beam limiting opening and wherein the charged particle deflector assembly is purely electrostatic, particularly wherein the charged particle deflector assembly does not include one or more magnetic deflectors.

9. The charged particle beam energy width reduction apparatus according to claim 1, wherein the first electrostatic charged particle deflector generates at least 60% of the dispersion provided at the beam limiting opening, particularly at least 90% of the dispersion provided at the beam limiting opening.

10. The charged particle beam energy width reduction apparatus according to claim 1, wherein the beam limiting opening is a beam limiting slit.

11. The charged particle beam energy width reduction apparatus according to claim 10, wherein the beam limiting slit has a width of 2 μm or below, particularly 500 nm or below.

12. The charged particle beam energy width reduction apparatus according to claim 1, further comprising a fifth deflector configured to deflect the primary charged particle beam in a direction orthogonal to a deflection direction of the first electrostatic charged particle deflector and the second electrostatic charged particle deflector.

13. A charged particle beam device having an optical axis, comprising:
a charged particle beam source configured to generated a primary charged particle beam;
a charged particle beam energy width reduction apparatus, comprising:
a first round lens configured to decelerate a primary charged particle beam and to focus the primary charged particle beam in a focusing plane;
a charged particle deflector assembly configured to generate dispersion in the focusing plane, the charged particle deflector assembly comprising:
a first electrostatic charged particle deflector arranged on the optical axis and comprising two flat conducting surfaces; and
a second electrostatic charged particle deflector comprising two flat conducting surfaces;
the charged particle beam energy width reduction apparatus further comprising:
a beam limiting opening in an aperture body positioned in the focusing plane and off-axis with respect to the optical axis;
the charged particle beam device further comprising:
an objective lens configured to focus the primary charged particle beam.

14. The charged particle beam device of claim 13, further comprising an entrance aperture opening configured to limit the beam current to less than 10 nA.

15. The charged particle beam device of claim 14, further comprising a condenser lens, wherein the charged particle beam energy width reduction apparatus is provided between the charged particle beam source and the condenser lens and wherein the entrance aperture opening is provided between the charged particle beam source and the charged particle beam energy width reduction apparatus.

16. A method of operating a charged particle beam device having a charged particle beam energy width reduction apparatus, comprising:
generating a primary charged particle beam;
focusing the primary charged particle beam in a focusing plane with a first round lens and decelerating the primary charged particle beam with the first round lens;
generating dispersion in the focusing plane with a charged particle deflector assembly comprising:
a first electrostatic charged particle deflector arranged on an optical axis and comprising two flat conducting surfaces; and
a second electrostatic charged particle deflector comprising two flat conducting surfaces;
the method further comprising:
reducing an energy width of the primary charged particle beam with a beam limiting opening in an aperture body positioned in the focusing plane and off-axis with respect to an optical axis.

17. The method of claim 16, further comprising:
reducing the generated dispersion with the charged particle deflector assembly further comprising:
a third electrostatic charged particle deflector comprising two flat conducting surfaces; and
a fourth electrostatic charged particle deflector arranged on the optical axis and comprising two flat conducting surfaces.

18. The method of claim 16, further comprising limiting the beam current to 10 nA or less.

19. The method of claim 16, wherein the first round lens reduces an energy of the primary charged particle beam to 500 eV or less.

20. The method of claim 16, wherein the charged particle beam device has a first mode of operation, in which the charged particle beam energy width reduction apparatus is switched on and has a second mode of operation, in which the charged particle beam energy width reduction apparatus is switched off such that the primary charged particle beam travels along an optical axis of the charged particle beam device.
